(19) United States
(12) Patent Application Publication
(10) Pub. No.: US 2024/0083741 A1
(43) Pub. Date: Mar. 14, 2024

(54) MEMS DEVICE

(71) Applicant: ROHM CO., LTD., Kyoto (JP)

(72) Inventors: Daisuke NISHINOHARA, Kyoto (JP); Hideaki HASHIMOTO, Kyoto (JP); Toma FUJITA, Kyoto (JP)

(73) Assignee: ROHM CO., LTD., Kyoto (JP)

(21) Appl. No.: 18/460,885

(22) Filed: Sep. 5, 2023

(30) Foreign Application Priority Data
Sep. 9, 2022 (JP) 2022-143952

(51) Int. Cl. B81B 3/00

(52) U.S. Cl. CPC B81B 3/0051; B81B 2201/0235; B81B 2201/0264; B81B 2201/042; B81B 2201/052; B81B 2203/0118; B81B 2203/0346

(57) ABSTRACT

The present disclosure provides a MEMS device having a movable portion. The MEMS device includes: a substrate; a recess, disposed in the substrate; the movable portion, hollowly supported in the recess; and a bump stop, hollowly supported in the recess and configured to restrict a movement of the movable portion by contacting the movable portion. The bump stop includes: a protruding portion, configured to contact the movable portion; and a shock absorbing portion, disposed between the protruding portion and the substrate and configured to absorb at least a part of an impact force applied to the protruding portion by elastic deformation.

### TECHNICAL FIELD

The present disclosure relates to a micro-electromechanical system (MEMS) device, and more particularly to an MEMS device having a bump stop.

### BACKGROUND

In an acceleration sensor using an MEMS structure, a detection unit including a capacitive element is formed. The capacitive element allows arranging a fixed electrode disposed in a substrate and a movable electrode disposed on a mass in an opposite manner. When acceleration is applied, the movable electrode moves relative to the fixed electrode, and a capacitance change of the capacitive element at this time point is measured to detect the acceleration. Since the acceleration is applied to the acceleration sensor, when the movable electrode is excessively close to the fixed electrode and when the movable electrode is attached to the fixed electrode by electrostatic force, a bump stop provided as protruding from the substrate to the mass is prevented from adhesion by separating the movable electrode and the fixed electrode by more than a certain distance (for example, referring to Patent document 1).

### PRIOR ART DOCUMENT

### Patent Publication

[Patent document 1] Japan Patent Publication No. 2009-500635

### BRIEF DESCRIPTION OF THE DRAWINGS

FIG. 1 is a layout diagram of an MEMS sensor according to a first embodiment of the present disclosure.

FIG. 2 is an enlarged top view of the vicinity A of a bump stop of the MEMS sensor in FIG. 1.

FIG. 3 is an enlarged perspective diagram of the vicinity A of a bump stop of the MEMS sensor in FIG. 1.

FIG. 4 is a layout diagram of an MEMS sensor according to a second embodiment of the present disclosure.

FIG. 5 is an enlarged top view of the vicinity B of a bump stop of the MEMS sensor in FIG. 4.

FIG. 6 is a layout diagram of an MEMS sensor according to a third embodiment of the present disclosure.

FIG. 7 is an enlarged top view of the vicinity C of a bump stop of the MEMS sensor in FIG. 6.

### DETAILED DESCRIPTION OF THE EMBODIMENTS

### First Embodiment

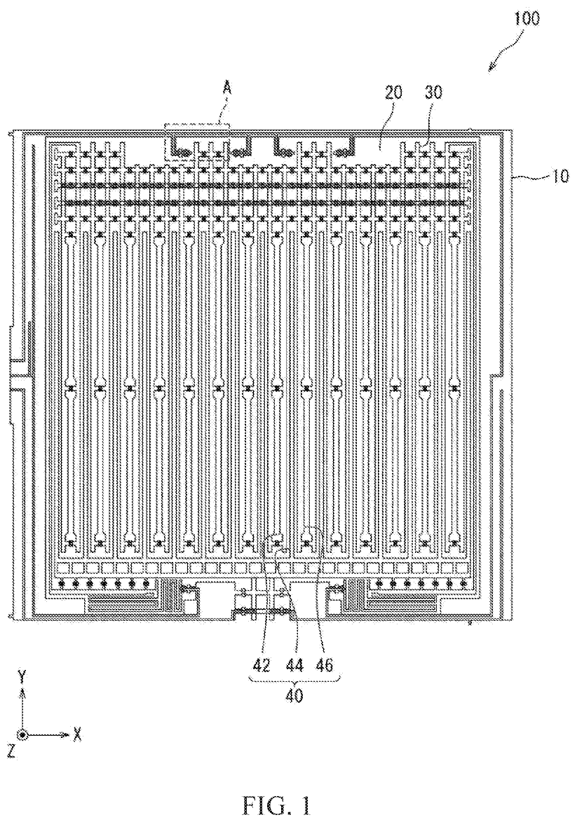

FIG. 1 shows a layout diagram of an overall MEMS sensor 100 according to a first embodiment of the present disclosure, wherein an acceleration sensor is taken as an example of the MEMS sensor.

The MEMS sensor 100 includes a substrate 10 including silicon, and a recess 20 disposed in the substrate 10. In the recess 20, there are a mass 30 hollowly supported in a movable state and movable electrodes 42 and 46 connected to the mass 30.

On the other hand, in the recess 20, there is a fixed electrode 44 supported in a fixed state by the substrate 10. The two movable electrodes 42 and 46 sandwiching the fixed electrode 44 and arranged opposite to each other in parallel form one set of capacitive element 40.

In the substrate 10, there is a wiring layer (not shown) individually connected to the movable electrodes 42 and 46 and the fixed electrode 44.

In the MEMS sensor 100, when acceleration is applied in the X-axis direction, the movable electrodes 42 and 46 connected to the mass 30 move relative to the fixed electrode 44 fixed at the substrate 10. By detecting a capacitance change based on a distance change between each of the movable electrodes 42 and 46 and the fixed electrode 44, the acceleration is detected.

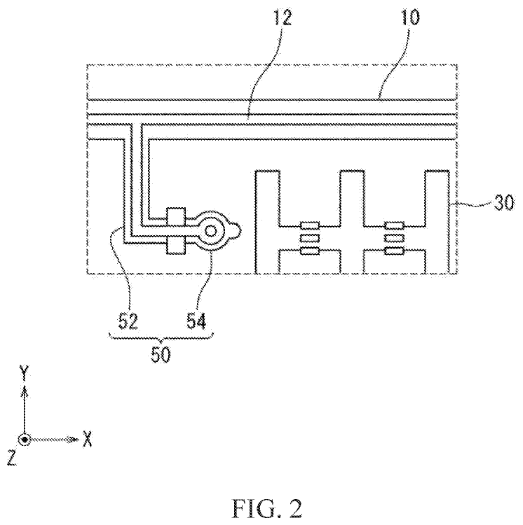

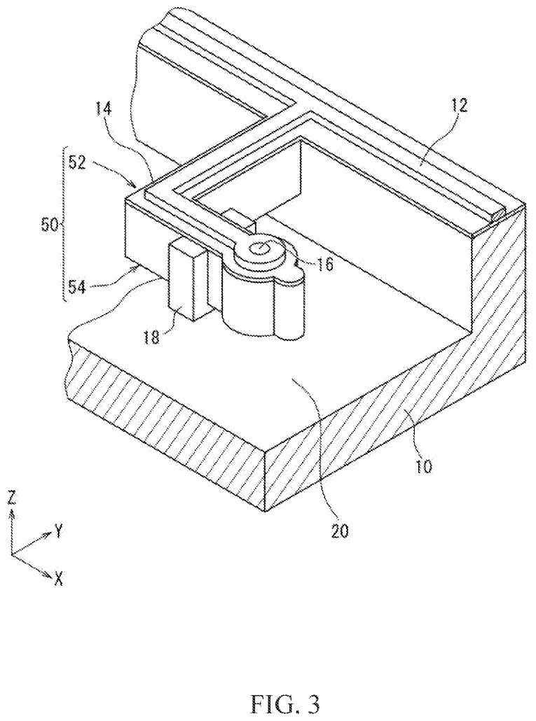

FIG. 2 shows an enlarged top view of the vicinity A of a bump stop of the MEMS sensor 100 shown by the dashed line in FIG. 1. FIG. 3 shows an enlarged perspective diagram of the vicinity A of the bump stop. In FIG. 2 and FIG. 3, the numerals or symbols same as those in FIG. 1 represent the same or equivalent parts.

As shown in FIG. 2 and FIG. 3, a bump stop 50 is disposed in the substrate 10 in order to restrict a movement of the mass 30 in the X-axis direction. As shown in FIG. 1, the bump stop 50 is disposed on both sides of the mass 30 (the same applies to the second and third embodiments below). The bump stop 50 is in the recess 20 disposed in the substrate 10, and includes a shock absorbing portion 52 extending as a cantilever along the Y-axis direction from the substrate 10, and a protruding portion 54 connected to an end portion of the shock absorbing portion 52 and extending along the X-axis direction. The bump stop 50 is formed by etching the substrate 10, and as shown in FIG. 3, is kept as hollow at a fixed end of the substrate 10. The bump stop 50 is similarly formed of, for example, silicon, as the substrate 10.

Moreover, preferably, the bump stop 50 and the mass 30 are connected by a wiring layer 12, and are kept at the same potential. The reason for the above is that a repulsive force can act between the two to prevent adhesion. In FIG. 3, the wiring layer 12 disposed on an insulation film 14 passes through a route 16 and is located below the insulation film 14, and is connected to the protruding portion 54 containing silicon.

In the MEMS sensor 100, by contacting the bump stop 50 with the mass 30, a movable range of the mass 30 is restricted. Accordingly, by separating the movable electrodes 42 and 46 connected to the mass 30 from the fixed electrode 44 by more than a certain distance, contact or adhesion of the movable electrodes 42 and 46 with the fixed electrode 44 can be prevented.

Moreover, if a large acceleration is applied to the MEMS sensor 100 and a large force (impact force) is applied in the X-axis direction within a short period of time (for example, 10 μsec), once the mass 30 comes into contact with the bump stop 50, the shock absorbing portion 52 absorbs at least a part of a shock by means of flexing in the X-axis direction. Accordingly, a force applied to the protruding portion 54 can be reduced, and breakage or bending of the protruding portion 54 can also be prevented.

As such, in the MEMS sensor 100 of the first embodiment of the present disclosure, with the bump stop 50 formed by the shock absorbing portion 52 and the protruding portion 54, shock resistance of the bump stop 50 is enhanced.

In the MEMS sensor 100 (the same applies to the MEMS sensor 30), although the shock absorbing portion 52 is configured to be a cantilever extending along the Y-axis direction from the substrate 10, a beam structured to wind around the recess 20 can also be provided for a structure that flexes along the X-axis direction when an impact force is received.

### Second Embodiment

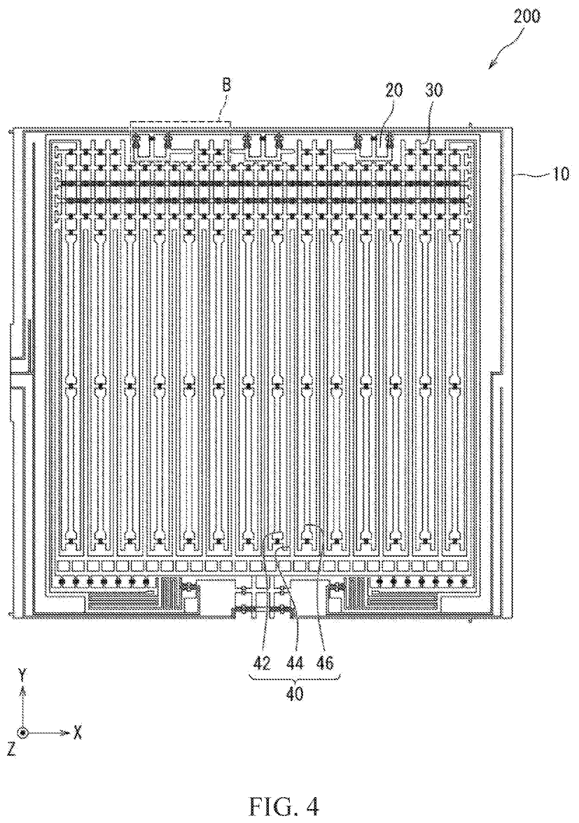

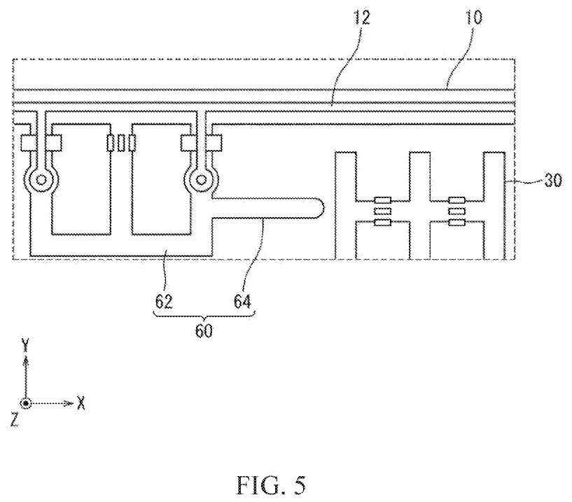

FIG. 4 shows a layout diagram of an overall MEMS sensor 200 according to a second embodiment of the present disclosure. FIG. 5 shows an enlarged top view of the vicinity B of a bump stop of the MEMS sensor 200 shown by the dashed line in FIG. 4. In FIG. 4 and FIG. 5, the numerals or symbols same as those in FIG. 1 and FIG. 2 represent the same or equivalent parts.

As shown in FIG. 5, a bump stop 60 of the MEMS sensor 200 is in the recess 20 disposed in the substrate 10, and includes a shock absorbing portion 62 including a grid-shaped beam (grid structure) extending out along the Y-axis direction from the substrate 10, and a protruding portion 64 connected to the shock absorbing portion 62 and extending along the X-axis direction. Similar to the bump stop 50, the bump stop 60 is formed by means of etching the substrate 10, and is similarly formed of, for example, silicon, as the substrate 10. Preferably, the bump stop 60 and the mass 30 are kept at the same potential by the wiring layer 12.

In the MEMS sensor 200 of the second embodiment of the present disclosure, when an impact force is applied to the MEMS sensor 200 along the X-axis direction, once the mass 30 comes into contact with the bump stop 60, the shock absorbing portion 62 of the grid structure absorbs a part of the shock by means of flexing. Accordingly, a shock applied to the protruding portion 64 can be reduced, and breakage or bending of the protruding portion 64 can also be prevented.

That is to say, as shown in FIG. 5, the shock absorbing portion 62 becomes a grid-shaped beam, and the grid-shaped beam includes three cantilever beams extending along the Y-axis direction from the substrate 10 and one beam connecting the cantilever beams to one another in the X-axis direction. When an impact force is applied to the protruding portion 64 in the X-axis direction, the grid alleviates the shock by means of deformation and elastic deformation, hence reducing a force applied to the protruding portion 64.

As such, in the MEMS sensor 200 of the second embodiment of the present disclosure, with the bump stop 60 formed by the shock absorbing portion 62 and the protruding portion 64, shock resistance of the bump stop 60 is enhanced.

Moreover, in FIG. 5, although the shock absorbing portion 62 is configured as a grid structure including three cantilever beams extending along the Y-axis direction and one beam connecting the cantilever beams with one another in the X-axis direction, the number of the beams is not limited to the values above for a grid structure that elastically deforms when a force is received in the X-axis direction.

### Third Embodiment

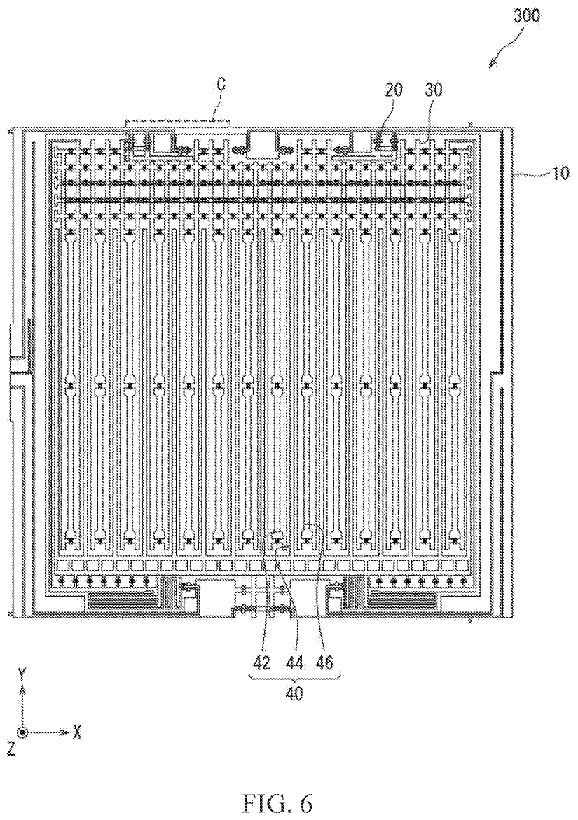

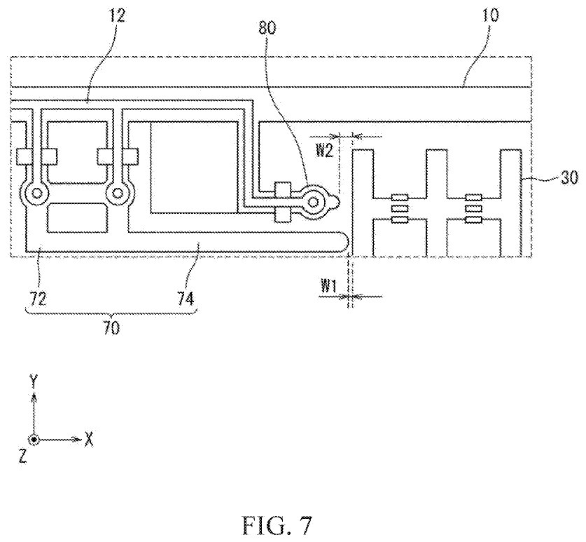

FIG. 6 shows a layout diagram of an overall MEMS sensor 300 according to a third embodiment of the present disclosure. FIG. 7 shows an enlarged top view of the vicinity C of a bump stop of the MEMS sensor 300 shown by the dashed line in FIG. 6. In FIG. 6 and FIG. 7, the numerals or symbols same as those in FIG. 1 and FIG. 2 represent the same or equivalent parts.

As shown in FIG. 7, in the MEMS sensor 300, there are a first bump stop 70 including a shock absorbing portion 72 and a protruding portion 74, and a second bump stop 80 fixed to the substrate 10. The protruding portion 74 of the first bump stop 70 and the second bump stop 80 are arranged in parallel in the X-axis direction.

A distance W1 between the protruding portion 74 of the first bump stop 70 and the mass 30 is less than a distance W2 between the second bump stop 80 and the mass 30 (W1<W2). Thus, when an impact force is applied to the mass 30 in the X-axis direction, the mass 30 first comes into contact with the protruding portion 74 of the first bump stop 70. Since the first bump stop 70 includes the shock absorbing portion 72 including beams in a grid structure, the shock absorbing portion 72 alleviates the shock by means of deformation and elastic deformation.

Moreover, although the mass 30 moves along the X-axis direction and comes into contact with the second bump stop 80, the impact force applied to the protruding portion 74 is alleviated by the shock absorbing portion 72, and so the second bump stop 80 is not damaged and a movable range of the mass 30 can be restricted.

As such, in the MEMS sensor 300 of the third embodiment of the present disclosure, with a combination of the first bump stop 70 having the shock absorbing portion 72 and the second bump stop 80, shock resistance of the second bump stop 80 is enhanced.

More particularly, in the MEMS sensor 300, because the second bump stop 80 is fixed to the substrate 10, a movable range of the mass 30 can be more accurately restricted.

Moreover, the number of beams of the shock absorbing portion 72 in a grid structure in FIG. 7 is not limited to the examples above. In addition, in FIG. 6 and FIG. 7, although the shock absorbing portion 72 is configured to be a grid structure, a cantilever structure as that in the first embodiment can also be implemented.

In the first to third embodiments of the present disclosure, description is provided by taking an acceleration sensor as an example. However, the present disclosure is extensively applicable to other MEMS devices having bump stops, such as print heads, digital micro mirror devices and pressure sensors.

### NOTES

The present disclosure provides a microelectromechanical systems (MEMS) device having a movable portion, the MEMS device comprising:
a substrate;
a recess, disposed in the substrate;
the movable portion, hollowly supported in the recess; and
a bump stop, hollowly supported in the recess and configured to restrict a movement of the movable portion by contacting the movable portion, wherein the bump stop includes:
   a protruding portion, configured to contact the movable portion; and a shock absorbing portion, disposed between the protruding portion and the substrate and configured to absorb at least a part of an impact force applied to the protruding portion by elastic deformation.

With the bump stop formed by the shock absorbing portion and the protruding portion, shock resistance of the bump stop is enhanced.

In the present disclosure, the protruding portion extends along a movable direction of the movable portion.

With the configuration, a movable range of the movable portion can be restricted.

In the present disclosure, the shock absorbing portion is a cantilever with a first end fixed to the substrate and a second end fixed to the protruding portion.

By structuring the shock absorbing portion to be a cantilever, the cantilever is accordingly deformed to absorb an impact force applied to the protruding portion.

In the present disclosure, the shock absorbing portion is a grid-shaped beam fixed to the substrate.

By structuring the shock absorbing portion to be a grid-shaped beam, the grid-shaped beam is accordingly deformed and can absorb an impact force applied to the protruding portion.

The present disclosure provides a microelectromechanical systems (MEMS) device having a movable portion, the MEMS device comprising:
a substrate;
a recess, disposed in the substrate;
the movable portion, hollowly supported in the recess;
a first bump stop, hollowly supported in the recess and configured to be elastically deformed by contacting the movable portion to absorb at least a part of an impact force applied from the movable portion; and
a second bump stop, hollowly supported in the recess and configured to restrict a movement of the movable portion by contacting the movable portion,
wherein a distance W1 between the movable portion and the first bump stop is less than a distance W2 between the movable portion and the second bump stop.

With the configuration, an impact force is absorbed by the first bump stop, and a movable range of the movable portion can be accurately restricted by the second bump stop.

In the present disclosure, the first bump stop includes: a protruding portion, configured to contact the movable portion; and a shock absorbing portion, disposed between the protruding portion and the substrate and configured to absorb at least a part of an impact force applied to the protruding portion by elastic deformation.

With the configuration, the first bump stop can absorb at least a part of an impact force from the movable portion, and reduce an impact force received by the second bump stop.

In the present disclosure, the second bump stop includes a protruding portion, which is fixed to the substrate and extends along a direction of movement of the movable portion. With the configuration, a movable range of the movable portion can be accurately restricted by the second bump stop.

### INDUSTRIAL APPLICABILITY

The present disclosure is applicable to MEMS sensors such as acceleration sensors or pressure sensors, and MEMS devices such as print heads and digital micro mirror devices.

1. A MEMS device having a movable portion, comprising:
a substrate;
a recess, disposed in the substrate;
the movable portion, hollowly supported in the recess; and
a bump stop, hollowly supported in the recess and configured to restrict a movement of the movable portion by contacting the movable portion, wherein the bump stop includes:
a protruding portion, configured to contact the movable portion; and
a shock absorbing portion, disposed between the protruding portion and the substrate and configured to absorb at least a part of an impact force applied to the protruding portion by elastic deformation.

2. The MEMS device of claim 1, wherein the protruding portion extends along a movable direction of the movable portion.

3. The MEMS device of claim 1, wherein the shock absorbing portion is a cantilever with a first end fixed to the substrate and a second end fixed to the protruding portion.

4. The MEMS device of claim 2, wherein the shock absorbing portion is a cantilever with a first end fixed to the substrate and a second end fixed to the protruding portion.

5. The MEMS device of claim 1, wherein the shock absorbing portion is a grid-shaped beam fixed to the substrate.

6. The MEMS device of claim 2, wherein the shock absorbing portion is a grid-shaped beam fixed to the substrate.

7. A MEMS device having a movable portion, comprising:
a substrate;
a recess, disposed in the substrate;
the movable portion, hollowly supported in the recess;
a first bump stop, hollowly supported in the recess and configured to be elastically deformed by contacting the movable portion to absorb at least a part of an impact force applied from the movable portion; and
a second bump stop, hollowly supported in the recess and configured to restrict a movement of the movable portion by contacting the movable portion, wherein
a distance between the movable portion and the first bump stop is less than a distance between the movable portion and the second bump stop.

8. The MEMS device of claim 7, wherein the first bump stop includes:
a protruding portion, configured to contact the movable portion; and
a shock absorbing portion, disposed between the protruding portion and the substrate and configured to absorb at least a part of an impact force applied to the protruding portion by elastic deformation.

9. The MEMS device of claim 7, wherein the second bump stop includes a protruding portion fixed to the substrate and extending along a direction of movement of the movable portion.
